(19) United States
(12) Patent Application Publication
(10) Pub. No.: US 2009/0065841 A1
(43) Pub. Date: Mar. 12, 2009

(54) SILICON OXY-NITRIDE (SiON) LINER, SUCH AS OPTIONALLY FOR NON-VOLATILE MEMORY CELLS

(76) Inventors: Assaf Shappir, Kiryat Ono (IL); Jun Sumino, Tokyo (JP)

Correspondence Address: EMPK & Shiloh, LLP;c/o Landon IP, Inc., 1700 Diagonal Road, Suite 450, Alexandria, VA, 22314, US

(21) Appl. No.: 11/850,727

(22) Filed: Sep. 6, 2007

(51) Int. Cl. H01L 29/788

(52) U.S. Cl. 257/315; 257/E29.3

(57) ABSTRACT

An improved contact etch stop liner (CESL) is provided, to reduce stress effects in NVM cells using a nitride charge-trapping layer (such as NROM). SiON (silicon oxy-nitride) may be used in lieu of SiN (silicon nitride), for the CESL. Or, the CESL may be processed to be discontinuous, to reduce stress effects, using either conventional SiN (silicon nitride) or SiON. Or, the CESL layer may be eliminated entirely, to reduce stress effects.

### TECHNICAL FIELD

The disclosure relates to techniques for fabricating semiconductor devices and, more particularly, to non-volatile memories (NVM), especially those containing a trapping layer, such as nitride read only memory (NROM) or other microelectronic cells or structures.

### BACKGROUND

### The Field Effect Transistor

The transistor is a solid state semiconductor device which can be used for amplification, switching, voltage stabilization, signal modulation and many other functions. Generally, a transistor has three terminals, and a voltage applied to a specific one of the terminals controls current flowing between the other two terminals.

The terminals of a field effect transistor (FET) are commonly named source, gate and drain. In the FET a small amount of voltage is applied to the gate in order to control current flowing between the source and drain. In FETs the main current appears in a narrow conducting channel formed near (usually primarily under) the gate. This channel connects electrons from the source terminal to the drain terminal. The channel conductivity can be altered by varying the voltage applied to the gate terminal, enlarging or constricting the channel and thereby controlling the current flowing between the source and the drain.

FIG. 1 illustrates a FET 100 comprising a p-type substrate, and two spaced-apart n-type diffusion areas—one of which will serve as the “source”, the other of which will serve as the “drain” of the transistor. The space between the two diffusion areas is the “channel”. A thin dielectric layer is disposed over the substrate in the neighborhood of the channel, and a “gate” structure is disposed over the dielectric layer atop the channel. (The dielectric under the gate is also commonly referred to as “gate oxide” or “gate dielectric”.) Electrical connections (not shown) may be made to the source, the drain, and the gate. The substrate may be grounded.

Generally, when there is no voltage on the gate, there is no electrical conduction (connection) between the source and the drain. As voltage (of the correct polarity) is applied to the gate, there is a “field effect” in the channel between the source and the drain, and current can flow between the source and the drain, and can be controlled by the voltage applied to the gate. In this manner, a small signal (gate voltage) can control a relatively large signal (current flow between the source and the drain).

### The Floating Gate Transistor

A floating gate transistor is generally a transistor structure, broadly based on the FET, as described hereinabove. As illustrated in FIG. 2, the floating gate transistor 200 has a source and a drain, but rather than having only one gate, it has two gates which are called control gate (CG) and floating gate (FG). It is this arrangement of control gate and floating gate which enables the floating gate transistor to function as a memory cell, as described hereinbelow.

The floating gate is disposed over tunnel oxide (comparable to the gate oxide of the FET). The floating gate is a conductor, the tunnel oxide is an insulator (dielectric material). Another layer of oxide (interpoly oxide, also a dielectric material) separates the floating gate from the control gate.

Since the floating gate is a conductor, and is surrounded by dielectric material, it can store a charge. Electrons can move around freely within the conductive material of the floating gate (which comports with the basic definition of a “conductor”).

Since the floating gate can store a charge, it can exert a field effect on the channel region between the source and the drain, in a manner similar to how a normal FET works, as described hereinabove. Mechanisms for storing charges on the floating gate structure, as well as removing charges from the floating gate are described hereinbelow.

Generally, if a charge is stored on the floating gate, this represents a binary “1”. If no charge is stored on the floating gate, this represents a binary “0”. (These designations are arbitrary, and can be reversed so that the charged state represents binary “0” and the discharged state represents binary “1”.) That represents the programming “half” of how a floating gate memory cell operates. The other half is how to determine whether there is a charge stored on the floating gate—in other words, to “read” the memory cell. Generally, this is done by applying appropriate voltages to the source, drain and gate terminals, and determining how conductive the channel is. Some modes of operation for a floating gate memory cell are described hereinbelow.

Normally, the floating gate non-volatile memory (NVM) cell has only a single “charge-storing area”—namely, the conductive floating gate (FG) structure, and can therefore only store a single bit of information (binary “1” or binary “0”). More recently, using a technology referred to as “multi-level cell” (MLC), two or more bits can be stored in and read from the floating gate cell.

### The Memory Cell

Another type of memory cell, called a “nitride, read only memory” (NROM) cell, has a charge-storage structure which is different from that of the floating gate memory cell and which permits charges to be stored in two separate charge-storage areas. Generally, the two separate charge storage areas are located within a non-conductive layer disposed between the gate and the underlying substrate, such as a layer of nitride formed in an oxide-nitride-oxide (ONO) stack underneath the gate. The non-conductive layer acts as a charge-trapping medium. Generally, electrical charges will stay where they are put in the charge-trapping medium, rather than being free to move around as in the example of the conductive floating gate of the floating gate memory cell. A first bit of binary information (binary “1” or binary “0”) can be stored in a first portion (such as the left-hand side) of the charge-trapping medium, and a second bit of binary information (binary “1” or binary “0”) can be stored in a second portion (such as the right-hand side) of the charge-trapping medium. An alternative viewpoint is that different charge concentrations can be considered for each bit of storage. Using MLC technology, at least two bits can be stored in and read from each of the two portions (charge storage areas) of the charge-trapping medium (for a total of 4 bits), similarly 3 bits or more than 4 bits may be identified. Other memory cells which are explicitly and specifically contemplated within the scope of the present disclosure include SONOS (Silicon Oxide Nitride Oxide Semiconductor), MONOS (Metal Oxide Nitride Semiconductor), and TANOS (Tantalum Nitride Oxide Semiconductor) all of which usually have one bit per cell without MLC technology (rather than the NROM two bits per cell without MLC) as well as split-gate (two separate nitride regions associated with the gate or channel) which usually has two bits per cell without MLC technology, all of which have a trapping layer, which is usually Nitride.

FIG. 3 illustrates a basic NROM memory cell, which may be viewed as an FET with an “ONO” structure (or “stack”) 321 inserted between the gate and the substrate. (One might say that the ONO structure is “substituted” for the gate oxide of the FET.)

The ONO structure is a stack (or “sandwich”) of bottom (lower) oxide 322, a charge-trapping material such as nitride 324, and a top (upper) oxide 326. The ONO structure may have, for example, an overall thickness of approximately 10-25 nm, such as 18 nm, as follows:
the bottom oxide layer 322 may be from 3 to 6 nm, for example 4 nm thick;
the middle nitride layer 324 may be from 3 to 8 nm, for example 4 nm thick; and
the top oxide layer 326 may be from 5 to 15 nm, for example 10 nm thick.

The NROM memory cell has two spaced apart diffusions 314 and 316 (which can function as source and drain, as discussed hereinbelow), and a channel region 320 defined in the substrate between the two diffusion regions 314 and 316, and a gate 328 disposed above the ONO stack 321.

In FIG. 3, the diffusions are labeled “N+”. This means that they are regions in the substrate that have been doped with an electron donor material, such as phosphorous or arsenic. These diffusions are typically created in a larger region which is p-type cell well (CW) doped with boron (or indium or both). This is the normal “polarity” for an NVM cell employing electron injection (but which may also employ hole injection, such as for erase). With opposite polarity (boron or indium implants in a n-type cell well), the primary injection mechanism would be for holes, which is generally accepted to be not as effective as electron injection. One skilled in the art will recognize that the concepts disclosed herein can be applied to opposite polarity devices.

The charge-trapping material 324 is non-conductive, and therefore, although electrical charges can be stored in the charge-trapping material, they are not free to move around, they will generally stay where they are stored. Nitride is a suitable charge-trapping material. Charge trapping materials other than nitride may also be suitable for use as the charge-trapping medium. One such material is silicon dioxide with buried polysilicon islands. A layer (324) of silicon dioxide with polysilicon islands would be sandwiched between the two layers of oxide (322) and (326). Alternatively, the charge-trapping layer 324 may be constructed by implanting an impurity, such as arsenic, into a layer of silicon dioxide deposited on top of the bottom oxide 322.

The memory cell 300 is generally capable of storing at least two bits of data—at least one bit(s) in a first storage area of the nitride layer 324 represented by the dashed circle 323, and at least one bit(s) in a second storage area of the nitride layer 324 represented by the dashed circle 321. Thus, the NROM memory cell can be considered to comprise two “half cells”, each half cell capable of storing at least one bit(s). It should be understood that a half cell is not a physically separate structure from another half cell in the same memory cell. The term “half cell”, as it may be used herein, is used herein only to refer to the “left” or “right” bit storage area of the ONO stack (nitride layer). The storage areas 321, 323 may variously be referred to as “charge storage areas”, “charge trapping areas”, and the like, throughout this document. (The two charge storage areas may also be referred to as the right and left “bits”.)

Each of the storage areas 321, 323 in the charge-trapping material 324 can exert a field effect on the channel region 320 between the source and the drain, in a manner similar to how a normal FET works, as described hereinabove (FIG. 2).

Generally, if a charge is stored in a given storage area of the charge-trapping material, this represents a binary “1”, and if no charge is stored in a given storage area of the charge-trapping material, this represents a binary “0”. (Again, these designations are arbitrary, and can be reversed so that the charged state represents binary “0” and the discharged state represents binary “1”.) That represents the programming “half” of how an NROM memory cell operates. The other half is how to determine whether there is a charge stored in a given storage area of the charge-trapping material—in other words, to “read” the memory cell. Generally, this is done by applying appropriate voltages to the diffusion regions (functioning as source and drain) and gate terminals, and determining how conductive the channel is.

Generally, one feature of NROM cells is that rather than performing “symmetrical” programming and reading, NROM cells are beneficially programmed and read “asymmetrically”, which means that programming and reading occur in opposite directions. The arrows labeled in FIG. 3 are arranged to illustrate this point. Programming may be performed in what is termed the “forward” direction and reading may be performed in what is termed the “opposite” or “reverse” direction.

Other similar charge trapping cells, such as MONOS, SONOS, TANOS and others may use “forward read” or symmetrical programming, while some trapping cells (such as split-gate) may use “reverse read” (asymmetrical or “forward read” symmetrical).

### “Reading” an NROM Cell

Reading an NROM memory cell may involve applying voltages to the terminals of the memory cell comparable to those used to read a floating gate memory cell, but reading may be performed in a direction opposite to that of programming. Generally, rather than performing “symmetrical” programming and reading (as is the case with the floating gate memory cell, described hereinabove), the NROM memory cell is usually programmed and read “asymmetrically”, meaning that programming and reading occur in opposite directions. This is illustrated by the arrows in FIG. 3. Programming is performed in what is termed the forward direction and reading is performed in what is termed the opposite or reverse direction. For example, generally, to program the right storage area 323 (in other words, to program the right “bit”), electrons flow from left (source) to right (drain). To read the right storage area 323 (in other words, to read the right “bit”), voltages are applied to cause electrons to flow from right to left, in the opposite or reverse direction. For example, generally, to program the left storage area 321 (in other words, to program the left “bit”), electrons flow from right (source) to left (drain). To read the left storage area 321 (in other words, to read the left “bit”), voltages are applied to cause electrons to flow from left to right, in the opposite or reverse direction. See, for example, U.S. Pat. No. 6,768,165.

### Memory Array Architecture Generally

Memory arrays are well known, and comprise a plurality (many, including many millions) of memory cells organized (including physically arranged) in rows (usually represented in drawings as going across the page, horizontally, from left-to-right) and columns (usually represented in drawings as going up and down the page, from top-to-bottom).

As discussed hereinabove, each memory cell comprises a first diffusion (functioning as source or drain), a second diffusion (functioning as drain or source) and a gate, each of which has to receive voltage in order for the cell to be operated, as discussed hereinabove. Generally, the first diffusions (usually designated “source”) of a plurality of memory cells are connected to a first bit line which may be designated “BL(n)”, and second diffusions (usually designated “drain”) of the plurality of memory cells are connected to a second bit line which may be designated “BL(n+1)”. Typically, the gates of a plurality of memory cells are connected to common word lines (WL).

The bitlines may be “buried bitline” diffusions in the substrate, and may serve as the source/drain diffusions for the memory cells. The wordlines may be polysilicon structures and may serve as the gate elements for the memory cells.

FIG. 4 illustrates an array of NROM memory cells (labeled “a” through “i”) connected to a number of word lines (WL) and bit lines (BL). For example, the memory cell “e” has its gate connected to WL(n), its source (left hand diffusion) is connected to BL(n), and its drain (right hand diffusion) is connected to BL(n+1). The nine memory cells illustrated in FIG. 4 are exemplary of many millions of memory cells that may be resident on a single chip.

Notice, for example that the gates of the memory cells “e” and “f” (to the right of “e”) are both connected to the same word line WL(n). (The gate of the memory cell “d” to the left of “e” is also connected to the same word line WL(n).) Notice also that the right hand terminal (diffusion) of memory cell “e” is connected to the same bit line BL(n+1) as the left-hand terminal (diffusion) of the neighboring memory cell “f”. In this example, the memory cells “e” and “f” have two of their three terminals connected together.

The situation of neighboring memory cells sharing the same connection—the gates of neighboring memory cells being connected to the same word line, the source (for example, right hand diffusion) of one cell being connected to the drain (for example left hand diffusion) of the neighboring cell—is even more dramatically evident in what is called “virtual ground architecture” wherein two neighboring cells actually share the same diffusion. In virtual ground array architectures, the drain of one memory cell may actually be the same diffusion which is acting as the source for its neighboring cell. Examples of virtual ground array architecture may be found in U.S. Pat. Nos. 5,650,959; 6,130,452; and 6,175,519, incorporated in their entirety by reference herein.

### Contact Etch Stop Layer (CESL)

FIG. 1 (FET), FIG. 2 (floating gate) and FIG. 3 (NROM), above, are somewhat stylised, omitting various common elements for the sake of illustrative clarity.

For example, a thin layer of metal salicide, such as cobalt silicide or titanium silicide or nickel salicide, may be formed atop the gate structure, and atop the source and drain diffusions (or two “agnostic” diffusions of an NROM cell). A dielectric layer may then be disposed over the entire device, to support upper level metalization such as wiring patterns, interconnects, word lines and bitlines which pass between several devices, as well as to external circuitry (not shown). This dielectric layer may be referred to as an inter level dielectric (ILD) layer.

Contacts must be opened through the ILD, to access the metal silicide, and effect contact with the gate (such as 328) and the two diffusions (such as 314 and 316). With reference to the diffusions, it is particularly important that, in the process of creating the contact, the underlying diffusion is not damaged. It is thereby known, and is common practice to first form a capping layer over the device, and said capping layer may act as an etch stop layer when etching the ILD to form the contacts.

The article entitled Method for Managing the Stress Due to the Strained Nitride Capping Layer in MOS Transistors, by Stephane Orain et al., IEEE Transactions on Electron Devices, Vol. 54, No. 4, April 2007, discusses stress in a nitride contact etch stop layer (CESL).

In some cases mechanical stress can be used advantageously to improve carrier mobility in a semiconductor device such as MOSFET (metal oxide semiconductor field effect transistor). In other cases, intrinsic mechanical stress can be disadvantageous, in the least since it may impose an undesired performance variable on the operation of the device.

NROM is one type of NVM cell commonly using a nitride charge trapping layer with an ONO stack structure. Data may be written in such memory cells by charging or discharging the nitride charge-trapping layer (such as 324, FIG. 3). Programming may involve injecting electrons into the charge-trapping layer, which increases the threshold voltage. Erasing may involve neutralizing the electrons, such as with hot hole injection (HHI), into the charge-trapping layer, which decreases the threshold voltage.

During device fabrication, a device may be exposed to plasma processing such as etching, ashing and thin film formation. Electrical charges may be induced by such plasma processing, and these charges may cause damage to or threshold voltage differences between memory cells.

During device fabrication, a device may be exposed to high temperatures, such as 1000 deg-C. anneal, which may induce undesirable stresses from the nitride capping layer.

With regard to NVM cells using a nitride charge-trapping layer (such as NROM), the disclosers have found that using SiN liner as a contact etch stop layer (CESL) imposes stress when doing temperature ramp to 1000 deg-C. (temperature ramp is inherent in some of the processing steps following liner formation, some of which may have been mentioned above).

A liner film structure covering the gate of CMOS and memory cells typically uses SiN (or p-SiN) as a contact etch stopping layer (CESL). The liner film structure is one of the deposition process parameters for charging during device fabrication. However, it may be difficult to remove (eliminate) the liner film structure because of its beneficial role in contact etch.

It is known that the CESL liner material (nitride) alters the mechanical stress that builds up on the wafer during the fabrication (due to such steps as rapid thermal anneals that increase the temperature to 1000 deg-C. in few seconds and then back down to room temperature) and that can affect the physical properties of the memory cells

It is believed that such mechanical stress alters the ONO layer's immunity to hot carrier damage during cycling and hence can change (degrade) the NROM cell's ability to store the trapped charge (data).

### Additional Background Information

Commonly-owned patents disclose structure and operation of NROM and related ONO memory cells. Some examples may be found in commonly-owned U.S. Pat. Nos. 5,768,192 and 6,011,725, 6,649,972 and 6,552,387.

Commonly-owned patents disclose architectural aspects of an NROM and related ONO array, (some of which have application to other types of NVM array) such as segmentation of the array to handle disruption in its operation, and symmetric architecture and non-symmetric architecture for specific products, as well as the use of NROM and other NVM array(s) related to a virtual ground array. Some examples may be found in commonly-owned U.S. Pat. Nos. 5,963,465, 6,285,574 and 6,633,496.

Commonly-owned patents also disclose additional aspects at the architecture level, including peripheral circuits that may be used to control an NROM array or the like. Some examples may be found in commonly-owned U.S. Pat. Nos. 6,233,180, and 6,448,750.

Commonly-owned patents also disclose several methods of operation of NROM and similar arrays, such as algorithms related to programming, erasing, and/or reading such arrays. Some examples may be found in commonly-owned U.S. Pat. Nos. 6,215,148, 6,292,394 and 6,477,084.

Commonly-owned patents also disclose manufacturing processes, such as the process of forming a thin nitride layer that traps hot electrons as they are injected into the nitride layer. Some examples may be found in commonly-owned U.S. Pat. Nos. 5,966,603, 6,030,871, 6,133,095 and 6,583,007.

Commonly-owned patents also disclose algorithms and methods of operation for each segment or technological application, such as: fast programming methodologies in all flash memory segments, with particular focus on the data flash segment, smart programming algorithms in the code flash and EEPROM segments, and a single device containing a combination of data flash, code flash and/or EEPROM. Some examples may be found in commonly-owned U.S. Pat. Nos. 6,954,393 and 6,967,896.

A more complete description of NROM and similar ONO cells and devices, as well as processes for their development may be found at “Non Volatile Memory Technology”, 2005 published by Saifun Semiconductor and materials presented at and through http://siliconnexus.com, both incorporated by reference herein in their entirety.

Where applicable, descriptions involving NROM are intended specifically to include related oxide-nitride technologies, including SONOS (Silicon-Oxide-Nitride-Oxide-Silicon), MNOS (Metal-Nitride-Oxide-Silicon), MONOS (Metal-Oxide-Nitride-Oxide-Silicon) and the like used for NVM devices. Further description of NVM and related technologies may be found at “Non Volatile Memory Technology”, 2005 published by Saifun Semiconductor; “Microchip Fabrication”, by Peter Van Zant, 5^{th} Edition 2004; “Application-Specific Integrated Circuits” by Michael John Sebastian Smith, 1997; “Semiconductor and Electronic Devices”, by Adir Bar-Lev, 2^{nd} Edition, 1999; “Digital Integrated Circuits” by Jan M. Rabaey, Anantha Chandrakasan and Borivoje Nikolic, 2^{nd} Edition, 2002 and materials presented at and through http://siliconnexus.com, “Design Considerations in Scaled SONOS Nonvolatile Memory Devices” found at: http://klabs.org/richcontent/MemoryContent/nvmt_symp/nvmts_{—}2000/presentations/bu_white_sonos_lehigh_univ.pdf, “SONOS Nonvolatile Semiconductor Memories for Space and Military Applications” found at http://klabs.org/richcontent/MemoryContent/nvmt_symp/nvmts_{—}2000/papers/adams_d.pdf, “Philips Research—Technologies—Embedded Nonvolatile Memories” found at: http://www.research.philips.com/technologies/ics/nvmemories/index.html, and “Semiconductor Memory: Non-Volatile Memory (NVM)” found at: http://www.ece.nus.edu.sg/stfpage/elezhucx/myweb/NVM.pdf, all of which are incorporated by reference herein in their entirety.

### GLOSSARY

Unless otherwise noted, or as may be evident from the context of their usage, any terms, abbreviations, acronyms or scientific symbols and notations used herein are to be given their ordinary meaning in the technical discipline to which the disclosure most nearly pertains. The following terms, abbreviations and acronyms may be used throughout the descriptions presented herein and should generally be given the following meaning unless contradicted or elaborated upon by other descriptions set forth herein. Some of the terms set forth below may be registered trademarks (®).
anisotropic literally, one directional. An example of an anisotropic process is sunbathing. Only surfaces of the body exposed to the sun become tanned. (see “isotropic”).
bit The word “bit” is a shortening of the words “binary digit.” A bit refers to a digit in the binary numeral system (base 2). A given bit is either a binary “1” or “0”. For example, the number 1001011 is 7 bits long. The unit is sometimes abbreviated to “b”. Terms for large quantities of bits can be formed using the standard range of prefixes, such as kilobit (Kbit), megabit (Mbit) and gigabit (Gbit). A typical unit of 8 bits is called a Byte, and the basic unit for 128 Bytes to 16K Bytes is treated as a “page”. That is the “mathematical” definition of “bit”. In some cases, the actual (physical) left and right charge storage areas of a NROM cell are conveniently referred to as the left “bit” and the right “bit”, even though they may store more than one binary bit (with MLC, each storage area can store at least two binary bits). The intended meaning of “bit” (mathematical or physical) should be apparent from the context in which it is used.
bit line or bitline (BL). A conductor connected to (or which may actually be) the drain (or source) of a memory cell transistor.
byte A byte is commonly used as a unit of storage measurement in computers, regardless of the type of data being stored. It is also one of the basic integral data types in many programming languages. A byte is a contiguous sequence of a fixed number of binary bits. In recent years, the use of a byte to mean 8 bits is nearly ubiquitous. The unit is sometimes abbreviated to “B”. Terms for large quantities of Bytes can be formed using the standard range of prefixes, for example, kilobyte (KB), megabyte (MB) and gigabyte (GB).
cap a term used to describe layers of a material disposed over another, dissimilar material, typically to protect the underlying material from damage during subsequent processing steps. A cap may be left in place, or removed, depending upon the situation.
Cell Well (CW) the cell well is an area in the silicon substrate that is prepared for functioning as a transistor or memory cell device by doping with an electron acceptor material such as boron or indium (p, electron acceptors or holes) or with an electron donor material such as phosphorous or arsenic (n, electron donors). The depth of a cell well is defined by the depth of the dopant distribution.
CHEI short for channel hot electron injection. sometimes abbreviated “CHE”.
CHISEL short for channel initiated secondary electron.
CMOS short for complementary metal oxide semiconductor. CMOS consists of n-channel and p-channel MOS transistors. Due to very low power consumption and dissipation as well as minimization of the current in “off” state, CMOS is a very effective device configuration for implementation of digital functions. CMOS is a key device in state-of-the-art silicon microelectronics.
   CMOS Inverter: A pair of two complementary transistors (a p-channel and an n-channel) with the source of the n-channel transistor connected to the drain of the p-channel one and the gates connected to each other. The output (drain of the p-channel transistor) is high whenever the input (gate) is low and the other way round. The CMOS inverter is the basic building block of CMOS digital circuits.
   NMOS: n-channel CMOS.
   PMOS: p-channel CMOS.
CMP short for chemical-mechanical polishing. CMP is a process, using both chemicals and abrasives, comparable to lapping, for removing material from a built up structure, resulting in a particularly planar resulting structure.
Dopant element introduced into semiconductor to establish either p-type (acceptors) or n-type (donors) conductivity; common dopants in silicon: p-type, boron, B, Indium, In; n-type phosphorous, P, arsenic, As antimony, Sb.
EEPROM short for electrically erasable, programmable read only memory. EEPROMs have the advantage of being able to selectively erase any part of the chip without the need to erase the entire chip and without the need to remove the chip from the circuit. The minimum erase unit is 1 Byte and more typically a full Page. While an erase and rewrite of a location appears nearly instantaneous to the user, the write process is usually slightly slower than the read process; the chip can usually be read at full system speeds.
EPROM short for erasable, programmable read only memory. EPROM is a memory cell in which information (data) can be erased and replaced with new information (data).
Erase a method to erase data on a large set of bits in the array, by applying a voltage scheme that inject holes or remove electrons in the bit set. This method causes all bits to reach a low Vt level.
FET short for field effect transistor. The FET is a transistor that relies on an electric field to control the shape and hence the conductivity of a “channel” in a semiconductor material. FETs are sometimes used as voltage-controlled resistors. The terminals of FETs are called gate, drain and source.
Flash memory Flash memory is a form of non-volatile memory (EEPROM) that can be electrically erased and reprogrammed. Flash memory architecture allows multiple memory locations to be erased or written in one programming operation.
FN tunneling Field emission—also called Fowler-Nordheim tunneling—is the process whereby electrons tunnel through a barrier in the presence of a high electric field. This quantum mechanical tunneling process is an important mechanism for thin barriers as those in metal-semiconductor junctions on highly-doped semiconductors. Using FN tunneling, electrons can be moved to the floating gate of a MOSFET memory cell.
half cell this term is sometimes used to refer to the two distinct charge storage areas (left and right bits) of an NROM memory cell.
HHI short for hot hole injection
isotropic literally, identical in all directions. An example of an isotropic process is dissolving a tablet in water. All exposed surfaces of the tablet are uniformly acted upon. (see “anisotropic”)
mask a layer of material which is applied over an underlying layer of material, and patterned to have openings, so that the underlying layer can be processed where there are openings. After processing the underlying layer, the mask may be removed. Common masking materials are photoresist and nitride. Nitride is usually considered to be a “hard mask”.
MLC short for multi-level cell. In the context of a floating gate (FG) memory cell, MLC means that at least two bits of information can be stored in the memory cell. In the context of an NROM memory cell, MLC means that at least four bits of information can be stored in the memory cell—at least two bits in each of the two charge storage areas.

MOS short for metal oxide semiconductor.

MOSFET short for metal oxide semiconductor field-effect transistor. MOSFET is by far the most common field-effect transistor in both digital and analog circuits. The MOSFET is composed of a channel of n-type or p-type semiconductor material, and is accordingly called an NMOSFET or a PMOSFET. (The ‘metal’ in the name is an anachronism from early chips where gates were metal; modern chips use polysilicon gates, but are still called MOSFETs).
nitride commonly used to refer to silicon nitride (chemical formula Si3N4). A dielectric material commonly used in integrated circuit manufacturing. Forms an excellent mask (barrier) against oxidation of silicon (Si). Nitride is commonly used as a hard mask or, in the case of a NVM memory cell having an ONO layer as a charge-trapping material.
n-type semiconductor in which concentration of electrons is higher than the concentration of “holes”. See p-type.
NROM sometimes used as an abbreviation for nitride read only memory. NVM short for non-volatile memory. NVM is computer memory that can retain the stored information even when not powered. Examples of non-volatile memory include read-only memory, flash memory, most types of magnetic computer storage devices (for example, hard disks, floppy disk drives, and magnetic tape), optical disc drives, and early computer storage methods such as paper tape and punch cards. Non-volatile memory is typically-used for the task of secondary storage, or long-term persistent storage. The most widely used form of primary storage today is a volatile form of random access memory (RAM), meaning that when the computer is shut down, anything contained in RAM is lost. Unfortunately most forms of non-volatile memory have limitations which male it unsuitable for use as primary storage. Typically non-volatile memory either costs more or performs worse than volatile random access memory. (By analogy, the simplest form of an NVM memory cell is a simple light switch. Indeed, such a switch can be set to one of two (binary) positions, and “memorize” that position.)
ONO short for oxide-nitride-oxide. ONO is used as a charge storage insulator consisting of a sandwich of thermally insulating oxide, and charge-trapping nitride.
oxide commonly used to refer to silicon dioxide (SiO2). Also known as silica. SiO2 is the most common insulator in semiconductor device technology, particularly in silicon MOS/CMOS where it is used as a gate dielectric (gate oxide); high quality films are obtained by thermal oxidation of silicon. Thermal SiO2 forms a smooth, low-defect interface with Si, and can be also readily deposited by chemical vapor deposition (CVD). Some particular applications of oxide are:
   LV Oxide short for low voltage oxide. LV refers to the process used to deposit the oxide.
   HV Oxide short for high voltage oxide. HV refers to the process used to deposit the oxide
   STI Oxide short for shallow trench oxide. Oxide-filled trenches are commonly used to separate one region (or device) of a semiconductor substrate from another region (or device).
Poly short for polycrystalline silicon (Si). Heavily doped poly Si is commonly used as a gate contact in silicon metal oxide semiconductor (MOS) and complementary metal oxide semiconductor (CMOS) devices;
p-type semiconductor in which concentration of “holes” is higher than the concentration of electrons. See n-type. Examples of p-type silicon include silicon doped (enhanced) with boron (B), Indium (In) and the like.
Program a method to program memory cells, or half cells, typically by applying a voltage scheme that injects electrons to increase the Vt of the cells or half cells being programmed.
PROM short for programmable read-only memory.
RAM short for random access memory. RAM refers to data storage formats and equipment that allow the stored data to be accessed in any order—that is, at random, not just in sequence. In contrast, other types of memory devices (such as magnetic tapes, disks, and drums) can access data on the storage medium only in a predetermined order due to constraints in their mechanical design.
Read a method to read the digital data stored in a memory cell.
resist short for photoresist. Also abbreviated “PR”. Photoresist is often used as a masking material in photolithographic processes to reproduce either a positive or a negative image on a structure, prior to etching (removal of material which is not masked). PR is usually washed off after having served its purpose as a masking material.
ROM short for read-only memory.
SEI short for secondary electron injection (or simply “secondary injection”). SEI occurs as a result of impact ionization by CHE electrons (e1) near the drain diffusion, generating an electron-hole pair (e2-h2), the hole (h2) of which continues into the substrate whereat another impact ionization results in another electron-hole pair (e3-h3), and the e3 electron becomes injected into the charge storage area(s) of the memory cell.
Si Silicon, a semiconductor.
SLC short for single level cell. In the context of a floating gate (FG) memory cell, SLC means that one bit of information can be stored in the memory cell. In the context of an NROM memory cell, SLC means that at least two bits of information can be stored in the memory cell.
SONOS Si-Oxide-Nitride-Oxide-Si, another way to describe ONO with the Si underneath and the Poly gate on top.
spacer a spacer, as the name implies, is a material (such as a layer of oxide) disposed on an element (such as a poly gate electrode). For example, sidewall spacers disposed on sides of a gate electrode cause subsequent implants to occur further away from the gate than otherwise (without the spacers in place).
STI short for shallow trench isolation
TEHH short for Tunnel Enhanced Hot Hole injection. TEHH is an “injection mechanism”.
Units of Length Various units of length may be used herein, as follows:
   meter (m) A meter is the SI unit of length, slightly longer than a yard.
      1 meter=˜39 inches. 1 kilometer (km)=1000 meters=˜0.6 miles. 1,000,000 microns=1 meter. 1,000 millimeters (mm)=1 meter. 100 centimeters (cm)=1 meter.
   micron (μm) one millionth of a meter (0.000001 meter); also referred to as a micrometer.
   mil 1/1000 or 0.001 of an inch; 1 mil=25.4 microns.
   nanometer (nm) one billionth of a meter (0.000000001 meter).
   Angstrom (Å) one tenth of a billionth of a meter. 10 Å=1 nm.
Voltage abbreviated v, or V. A voltage can be positive or negative (or zero). Usually, a negative voltage is preceded by a minus sign (−). Sometimes a positive voltage is preceded by a plus sign (+), or no sign at all. A number of voltages are relevant with regard to operating a memory cell, and are typically designated by the capital letter “V”, followed by another letter or letters. Some exemplary voltages of interest are:
   KeV short for kilo (thousand) electron volts
   Vt short for threshold voltage
   Vs short for source voltage
   Vd short for drain voltage
   Vg short for gate voltage
   Vbl short for bitline voltage. (the bitline may function as source or drain)
   Vwl short for wordline voltage (which typically is the same as Vg)
word line or wordline, (WL). A conductor normally connected to the gate of a memory cell transistor. The wordline may actually be the gate electrode of the memory cell.
write a combined method, usually involving first erasing a large set of bits, then programming new data into the bit set; the erase step is not required but it is customary.

In addition to the above, some abbreviations that may be used herein, or in a provisional application from which this non-provisional application claims priority, include:

ILD short for inter-layer (or inter-level) dielectric, typically oxide.
IMD short for inter-metal dielectric, typically oxide.
RAC short for retention after cycling
Gm relates to transconductance (analogous to gain)
DVde delta Vde drain erase voltage gate fixed, negative
STI short for shallow trench isolation
Ld short for (channel) length drawn
ANL short for ANneaL

### BRIEF DESCRIPTION (SUMMARY)

According to the disclosure, generally, an improved nitride liner is provided. Nitride (SiN) liners may be used as part of the IMD (inter metal dielectric) in optionally a copper process. Nitride liners may also be used as a contact etch stopping layer (CESL).

In the main hereinafter, nitride liners used in non-volatile memory (NVM) cells are discussed, and should be considered to be exemplary of other uses for the nitride liners disclosed herein.

According to the disclosure, generally, an improved contact etch stop liner (CESL) is provided, to reduce stress effects in NVM cells using a nitride charge-trapping layer (such as NROM).

The techniques disclosed herein may be applicable to most NVM devices including, but not limited to, NROM (sometimes referred to as Nitride Read Only Memory), SONOS (Semiconductor Oxide Nitride Oxide Semiconductor; Silicon-Oxide-Nitride-Oxide-Silicon), SANOS (Silicon-Aluminum Oxide-Nitride-Oxide-Silicon), MANOS (Metal-Aluminum Oxide-Nitride-Oxide-Silicon), TANOS (Tantalum-Aluminum Oxide-Nitride-Oxide-Silicon) and Floating Gate (FG) devices.

Generally, in one embodiment, SiON (silicon oxy-nitride) is used in lieu of SiN (silicon nitride), for the nitride liner or CESL. When SiON is used, intrinsic stress may be reduced. The SiON may be p-SiON (plasma-enhanced SiON deposition).

Generally, in another embodiment, a nitride (SiN) layer may be processed to be discontinuous, to reduce stress effects. This technique can also be used in conjunction with a silicon oxy-nitride (SiON) CESL.

Generally, in another embodiment, a CESL layer may be eliminated entirely, to reduce stress effects.

According to the disclosure, a non-volatile memory (NVM) cell may comprise: a channel defined between two diffusions in a semiconductor substrate; a charge storage stack or element disposed atop the channel; a gate electrode disposed atop the charge storage stack or element; and a contact etch stop layer (CESL) deposited as a thin film, covering the gate and diffusions; wherein: the CESL comprises silicon oxy-nitride (SiON). The NVM cell may be an NROM cell. The CESL may have a thickness in the range of 10 nm-200 nm, such as 20 nm-70 nm. The CESL may also cover the gate electrode. The CESL may extend as a continuous layer over the two diffusions and the gate electrode. The CESL may extend as a discontinuous layer over the two diffusions and the gate electrode and comprises a material selected from the group consisting of silicon oxy-nitride (SiON) and silicon nitride (SiN). The CESL may comprise separate segments over the two diffusions.

### BRIEF DESCRIPTION OF THE DRAWING(S)

Reference will be made in detail to embodiments of the disclosure, examples of which may be illustrated in the accompanying drawing figures (FIGs). The figures are intended to be illustrative, not limiting. Although the disclosure is generally described in the context of these embodiments, it should be understood that it is not intended to limit the disclosure to these particular embodiments.

Certain elements in selected ones of the figures may be illustrated not-to-scale, for illustrative clarity. The cross-sectional views, if any, presented herein may be in the form of “slices”, or “near-sighted” cross-sectional views, omitting certain background lines which would otherwise be visible in a true cross-sectional view, for illustrative clarity. In some cases, hidden lines may be drawn as dashed lines (this is conventional), but in other cases they may be drawn as solid lines.

If shading or cross-hatching is used, it is intended to be of use in distinguishing one element from another (such as a cross-hatched element from a neighboring un-shaded element. It should be understood that it is not intended to limit the disclosure due to shading or cross-hatching in the drawing figures.

Elements of the figures may (or may not) be numbered as follows. The most significant digits (hundreds) of the reference number correspond to the figure number. For example, elements of FIG. 1 are typically numbered in the range of 100-199, and elements of FIG. 2 are typically numbered in the range of 200-299. Similar elements throughout the figures may be referred to by similar reference numerals. For example, the element 199 in FIG. 1 may be similar (and possibly identical) to the element 299 in FIG. 2. Throughout the figures, each of a plurality of elements 199 may be referred to individually as 199a, 199b, 199c, etc. Such relationships, if any, between similar elements in the same or different figures will become apparent throughout the specification, including, if applicable, in the claims and abstract.

Throughout the descriptions set forth in this disclosure, lowercase numbers or letters may be used, instead of subscripts. For example Vg could be written V_{g}. Generally, lowercase is preferred to maintain uniform font size. Regarding the use of subscripts (in the drawings, as well as throughout the text of this document), sometimes a character (letter or numeral) is written as a subscript—smaller, and lower than the character (typically a letter) preceding it, such as “Vₛ” (source voltage) or “H₂O” (water). For consistency of font size, such acronyms may be written in regular font, without subscripting, using uppercase and lowercase—for example “Vs” and “H20”.

Conventional electronic components may be labeled with conventional schematic-style references comprising a letter (such as A, C, Q, R) indicating the type of electronic component (such as amplifier, capacitor, transistor, resistor, respectively) followed by a number indicating the iteration of that element (such as “1” meaning a first of typically several of a given type of electronic component). Components such as resistors and capacitors typically have two terminals, which may be referred to herein as “ends”. In some instances, “signals” are referred to, and reference numerals may point to lines that carry said signals. In the schematic diagrams, the various electronic components are connected to one another, as shown. Usually, lines in a schematic diagram which cross over one another and where there is a dot at the intersection of the two lines are connected with one another, else (if there is no dot at the intersection) they are typically not connected with one another.

FIG. 1 is a stylized cross-sectional view of a field effect transistor (FET), according to the prior art. To the left of the figure is a schematic symbol for the FET.

FIG. 2 is a stylized cross-sectional view of a floating gate memory cell, according to the prior art. To the left of the figure is a schematic symbol for the floating gate memory cell.

FIG. 3 is a stylized cross-sectional view of a two bit NROM memory cell of the prior art. To the left of the figure is a schematic symbol for the NROM memory cell.

FIG. 4 is a diagram of a memory cell array with NROM memory cells, according to the prior art.

FIG. 5 is a cross-sectional view of an embodiment of an exemplary NVM cell using a nitride charge-trapping layer (such as NROM), according to an embodiment of the disclosure.

FIG. 6 is a cross-sectional view of an embodiment of an exemplary NVM cell using a nitride charge-trapping layer (such as NROM), according to an embodiment of the disclosure.

FIG. 7 is a cross-sectional view of an embodiment of an exemplary NVM cell using a nitride charge-trapping layer (such as NROM), according to an embodiment of the disclosure.

FIG. 8 is a cross-sectional view of an embodiment of an exemplary NVM cell using a nitride charge-trapping layer (such as SONOS, MONOS, TANOS), according to an embodiment of the disclosure.

FIG. 9 is a cross-sectional view of an embodiment of an exemplary NVM cell using a nitride charge-trapping layer (such as NROM), according to an embodiment of the disclosure.

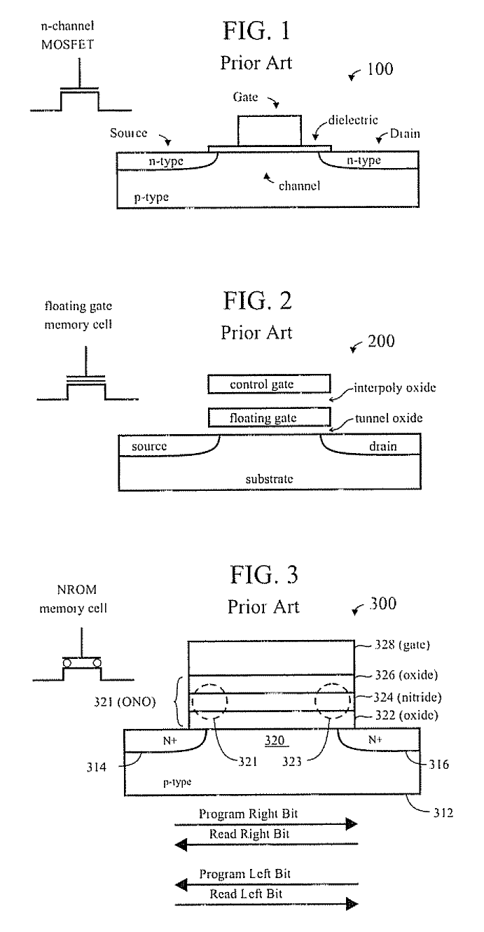

### DETAILED DESCRIPTION

Although various features of the disclosure may be described in the context of a single embodiment, the features may also be provided separately or in any suitable combination. Conversely, although the disclosure may be described herein in the context of separate embodiments for clarity, the disclosure may also be implemented in a single embodiment. Furthermore, it should be understood that the disclosure can be carried out or practiced in various ways, and that the disclosure can be implemented in embodiments other than the exemplary ones described hereinbelow. The descriptions, examples, methods and materials presented in the in the description, as well as in the claims, should not be construed as limiting, but rather as illustrative.

### A First Embodiment

FIG. 5 shows an exemplary non-volatile memory (NVM) cell 500 (compare 300), according to an embodiment of the disclosure. Although more details of the NVM cell's construction may be shown in FIG. 5 than in FIG. 3, some details of the cell's construction may nevertheless be omitted, for illustrative clarity. Also, some features of the cell may be exaggerated, or stylized, also for illustrative clarity. The principles discussed in this, and subsequent embodiments, are merely exemplary, and can readily be applied to other architectures.

Generally, a charge storage stack 521 (compare 321), which may be an ONO stack, is disposed atop a channel 520 (compare 320) which is defined (located) between two (source or drain) diffusions 514 and 516 (compare 314 and 316) in a substrate 512 (compare 312). A gate electrode 528 (compare 328) is formed atop the ONO stack 521. Sidewall spacers 529 may be formed on opposite sides of the gate electrode 528. Further process steps, and structures resulting from the process steps will now be described, which generally involve structures 530 overlying the basic memory cell to provide for interconnect.

A layer of thin metal (cobalt or titanium or nickel) 532 may be deposited atop the diffusions 514 and 516, such as having a thickness in the range of 20 nm-200 nm. The metal is then silicided using a conventional salicidation process. (No patterning is necessary. Silicidation is self-aligned to the exposed silicon/poly-silicon.) The layer 532 also covers the gate 528, where it is labeled “534”. This layer 532 is generally for the purpose of reducing the sheet resistance of the diffusion and poly-silicon areas.

Next, a thin film cover liner 536 is deposited on the surface of the substrate 512, covering the entire NVM cell 500 (and neighboring cells on the wafer), including covering the gate electrode 528 and the two diffusions 514 and 516.

The cover liner 536 is deposited as a continuous layer, and may have a thickness in the range of 10 nm-200 nm.

Whereas a cover liner is typically (in the prior art) silicon nitride (SiN), according to an embodiment of the disclosure the cover liner 536 is formed as a continuous layer of silicon oxy-nitride (SiON), and may have a thickness in the range of 10 nm-200 nm such as 20 nm-70 nm.

SiON, as the chemical formulation implies, has oxygen incorporated into the silicon nitride film during the deposition process. Optionally, the oxygen is included by reacting N2O, NH3 and SiH4 in an N2 ambient. SiON exhibits less stress than Nitride and its contact etch stop properties can be tailored to correspond to that of silicon nitride. Besides its use as a passivation layer (it can be modified to allow or block UV transmission) it may also be used as gate oxide material (where it helps prevent boron out diffusion).

It may be noted that, when a thin film of SiON is applied as a liner structure, RAC characteristics may dramatically be improved, due to reduced stress and optionally protection from plasma induced charges.

Next, an inter-layer dielectric (ILD) layer 538 is disposed over the cover liner 536. The ILD layer 538 may be oxide (SiO2), deposited by a conventional oxide deposition process to a thickness in the range of 700 nm-1200 nm.

Next, contact openings (or “vias”) 540 are formed through the ILD layer 538, such as by using a conventional contact etch process. This process etches the ILD material, and proceeds down to the oxy-nitride cover liner 536, which functions as a “contact etch stop layer” (CESL). The dashed line towards the bottom of the opening 540 illustrates that the contact etch step stops on the CESL 536. A subsequent conventional etch step, such as using a dry plasma reactive ion etch, may be performed to etch through the CESL 536 at the bottom of the opening 540 and to etch stop on metal silicide or silicon. This is a conventional process. In this manner, the openings 540 (two shown) extend downward, completely through the ILD layer, to the diffusions 514 and 516 (or to the salicide 532 on the two diffusions).

Next, the opening 540 may be filled (plugged) with a conductive material which may be metal, such as tungsten, or with poly (polysilicon) using a conventional deposition process, with excess metal or poly overfilling the opening 540 being polished off, such as by using a conventional chemical-mechanical polishing process, or by an etch-back process or other similar processes. The conductive contact material is not specifically shown (it fills the opening 540), for illustrative clarity.

A conventional SiN contact etch stop layer (CESL) may develop stresses from subsequent high-temperature processes that adversely impact cell performance. For example, in a case where the liner (CESL) is deposited before the CMOS source/drain implant, the device may be subsequently subjected to a 1000 deg-C. implant anneal step. In other cases, such as when the liner is deposited during the BEOL (back end of line), a nitride liner may be deposited before every metal (such as copper) layer (there may be several metal layers).

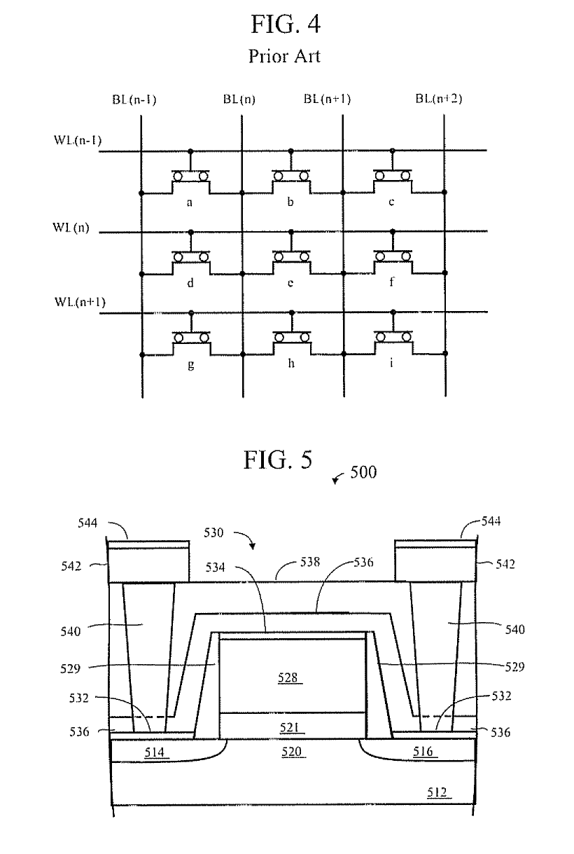

Next, a metal layer 542 may be deposited atop the ILD 538, and patterned, using conventional deposition and lithography processes, for the purpose of connecting the cell 500 to other cells (not shown, see FIG. 4) and/or external control circuitry (not shown).

Finally, a thick layer 544 of either oxide or nitride or oxy-nitride, or other passivating material may be deposited onto the metal layer 542. For example, in a single metal process, this would be the passivation layer that is used to protect the die during bonding and packaging. If it is a multi-metal process, then this would be a thin layer that is a precursor to the inter-metal dielectric (IMD) layer. This is, optionally, a representative of copper metallization. Silicon Oxy-Nitride (SiON), as disclosed herein, can be used in conjunction with an optional copper metallization.

### A Second Embodiment

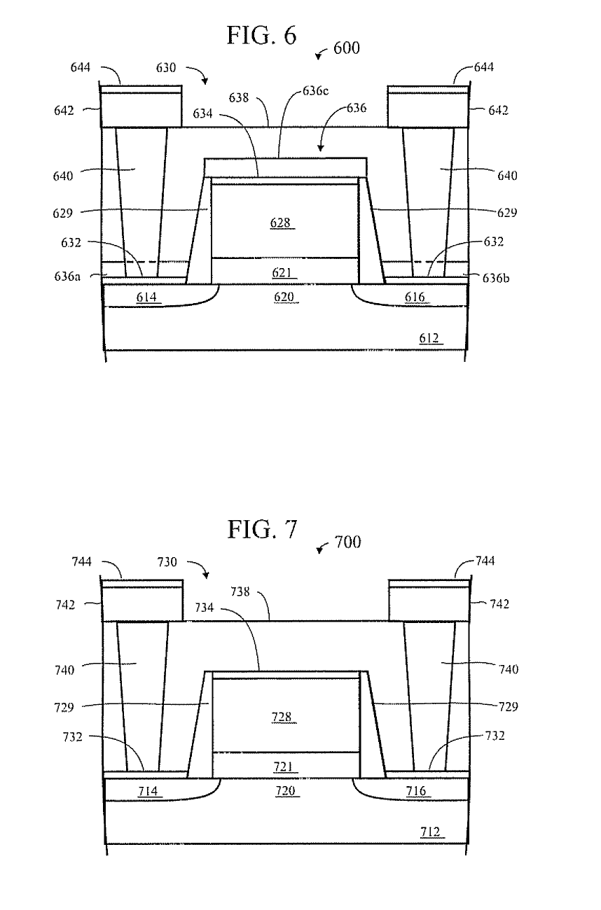

FIG. 6 shows a non-volatile memory (NVM) cell 600 (compare 300, compare 500), according to an embodiment of the disclosure. Although more details of the NVM cell's construction may be shown in FIG. 6 than in FIG. 3, some details of the cell's construction may nevertheless be omitted, for illustrative clarity. Also, some features of the cell may be exaggerated, or stylized, also for illustrative clarity.

Generally, in this embodiment, a nitride (SiN) contact etch stop layer (CESL) may be processed to be discontinuous, to reduce stress effects. This technique can also be used in conjunction with a silicon oxy-nitride (SiON) CESL. Generally, the liner can be cut, wherever it is flat and with adequate margins around contacts, using conventional photolithography techniques such as photoresist, masking, etching, and the like.

Generally, in FIG. 6, the numbering of elements is simply incremented by +100 over comparable (substantially identical) elements in FIG. 5, for example:
FIG. 6 FIG. 5
substrate 612 substrate 512
diffusions 614, 616 diffusions 514, 516
channel 620 channel 620
ONO stack 621 ONO stack 521
gate 628 gate 528
interconnect structures 630 interconnect structures 530
salicide 632 salicide 532
salicide 634 salicide 534
CESL 636 CESL 536
contact openings 640 contact openings 540
metal layer 642 metal layer 542
passivating material 644 passivating material 544

Generally, a charge storage stack 621 (compare 321, also 521), which may be an ONO stack, is disposed atop a channel 620 (compare 320, also 520) which is defined (located) between two (source or drain) diffusions 614 and 616 (compare 314 and 316, also 4\514 and 516) in a substrate 612 (compare 312, also 512). A gate electrode 628 (compare 328, also 528) is formed atop the ONO stack 621. Sidewall spacers 629 may be formed on opposite sides of the gate electrode 628. Further process steps, and structures resulting from the process steps will now be described, which generally involve structures 630 overlying the basic memory cell to provide for interconnect.

A layer of thin metal (cobalt or titanium or nickel) 632 may be deposited atop the diffusions 614 and 616 such as having a thickness in the range of 20 nm-200 nm. The metal is then silicided using a conventional salicidation process. (No patterning is necessary. Silicidation is self aligned to the exposed silicon/poly-silicon.) The layer 632 also covers the gate 628, where it is labeled “634”. This layer 632 is generally for the purpose of reducing the sheet resistance of the diffusion and poly-silicon areas.

Next, a thin film cover liner, generally designated 636, is deposited on the surface of the substrate 612, covering the entire NVM cell 600 (and neighboring cells on the wafer), including covering the gate electrode 628 and the two diffusions 614 and 616.

The cover liner 636 is deposited as a continuous layer, and may have a thickness in the range of 10 nm-200 nm.

The cover liner 636, which may act as a contact etch stop layer (CESL) may be silicon oxy-nitride (SiON), as discussed in the first embodiment, or may simply be conventional nitride (SiN).

After depositing the CESL 636, conventional photolithography techniques are used to pattern the layer 636 so that, rather than being continuous (as in the previous, first embodiment) it is segmented (discontinuous), having separate segments 636a and 636b of the CESL 636 remaining over the two diffusions, 614 and 616, respectively. Additionally, a segment 636c remains over the gate 628 (such as over the gate salicide 634).

Next, as in the previous (first) embodiment, an inter-layer dielectric (ILD) layer 638 is disposed over the cover liner 636. The ILD layer 638 may be oxide (SiO2), deposited by a conventional oxide deposition process to a thickness in the range of 700 nm-1200 nm.

Next, contact openings (or “vias”) 640 are formed through the ILD layer 638, such as by using a conventional contact etch process. This process etches the ILD material, and proceeds down to the oxy-nitride cover liner 636, which functions as a “contact etch stop layer” (CESL). The dashed line towards the bottom of the opening 640 illustrates that the contact etch step stops on the CESL 636. A subsequent conventional etch step, such as using a dry plasma reactive ion etch, may be performed to etch through the CESL 636 at the bottom of the opening 640 and to etch stop on silicon. This is a conventional process.

Next, the opening 640 may be filled (plugged) with metal, such as tungsten, or with poly (polysilicon) using a conventional deposition process, with excess metal or poly overfilling the opening 640 being polished off, such as by using a conventional chemical-mechanical polishing process, or by an etch-back process or other similar processes. This is a conventional process, and although the CESL 636 is shown at the bottom of the opening 640, it will be understood that it is removed prior to the next step of filling the opening with a conductive contact material. The conductive contact material is not specifically shown (it fills the opening 640), for illustrative clarity.

Because the CESL layer is segmented, although individual segments may accumulate stresses, such as from a subsequent 1000 deg-C. implant anneal step, since the segments are disconnected from one another, the effect on cell performance may be greatly reduced.

Next, a metal layer 642 may be deposited, and patterned, using conventional deposition and lithography processes, for the purpose of connecting the cell 600 to other cells (not shown, see FIG. 4) and/or external control circuitry (not shown).

Finally, a thick layer 644 of either oxide or nitride or oxy-nitride, or other passivating material may be deposited onto the metal layer 642. For example, in a single metal process, this would be the passivation layer that is used to protect the die during bonding and packaging. If it is a multi-metal process, then this would be a thin layer that is a precursor to the inter-metal dielectric (IMD) layer.

### A Third Embodiment

FIG. 7 shows a non-volatile memory (NVM) cell 700 (compare 300, compare 500, compare 600), according to an embodiment of the disclosure. Although more details of the NVM cell's construction may be shown in FIG. 7 than in FIG. 3, some details of the cell's construction may nevertheless be omitted, for illustrative clarity. Also, some features of the cell may be exaggerated, or stylized, also for illustrative clarity.

Generally, in this embodiment, no nitride (SiN) contact etch stop layer (CESL) is used.

Generally, in FIG. 7, the numbering of elements is simply incremented by +200 over comparable (substantially identical) elements in FIG. 5, for example:
FIG. 7 FIG. 5
substrate 712 substrate 512
diffusions 714, 716 diffusions 514, 516
channel 720 channel 720
ONO stack 721 ONO stack 521
gate 728 gate 528
interconnect structures 730 interconnect structures 530
salicide 732 salicide 532
salicide 734 salicide 534
contact openings 740 contact openings 540
metal layer 742 metal layer 542
passivating material 744 passivating material 544

Generally, a charge storage stack 721 (compare 321), which may be an ONO stack, is disposed atop a channel 720 (compare 320) which is defined (located) between two (source or drain) diffusions 714 and 716 (compare 314 and 316) in a substrate 712 (compare 312). A gate electrode 728 (compare 328) is formed atop the ONO stack 721. Sidewall spacers 729 may be formed on opposite sides of the gate electrode 728. Further process steps, and structures resulting from the process steps will now be described, which generally involve structures 730 overlying the basic memory cell to provide for interconnect.

A layer of thin metal (cobalt or titanium or nickel) 732 may be deposited atop the diffusions 714 and 716, such as having a thickness in the range of 20 nm-200 nm. The metal is then silicided using a conventional salicidation process. (No patterning is necessary. Silicidation is self aligned to the exposed silicon/poly-silicon.) The layer 732 also covers the gate 728, where it is labeled “734”. This layer 732 is generally for the purpose of reducing the sheet resistance of the diffusion and poly-silicon areas.

Next, as in the previous (first) embodiment, an inter-layer dielectric (ILD) layer 738 is disposed over the cover liner 736. The ILD layer 738 may be oxide (SiO2), deposited by a conventional oxide deposition process to a thickness in the range of 700 nm-1200 nm.

Next, contact openings (or “vias”) 740 are formed through the ILD layer 738, such as by using a conventional contact etch process. Since there is no nitride liner to act as a contact etch stop, the metal silicide 732 or 734 may act as the contact etch stop.

Next, the opening 740 may be filled (plugged) with metal, such as tungsten, or with poly (polysilicon) using a conventional deposition process, with excess metal or poly overfilling the opening 740 being polished off, such as by using a conventional chemical-mechanical polishing process, or by an etch-back process or other similar processes. The conductive contact material is not specifically shown (it fills the opening 740), for illustrative clarity.

Next, a metal layer 742 may be deposited, and patterned, using conventional deposition and lithography processes, for the purpose of connecting the cell 700 to other cells (not shown, see FIG. 4) and/or external control circuitry (not shown).

Finally, a thick layer 744 of either oxide or nitride or oxy-nitride, or other passivating material may be deposited onto the metal layer 742. For example, in a single metal process, this would be the passivation layer that is used to protect the die during bonding and packaging. If it is a multi-metal process, then this would be a thin layer that is a precursor to the inter-metal dielectric (IMD) layer.

### A Fourth Embodiment

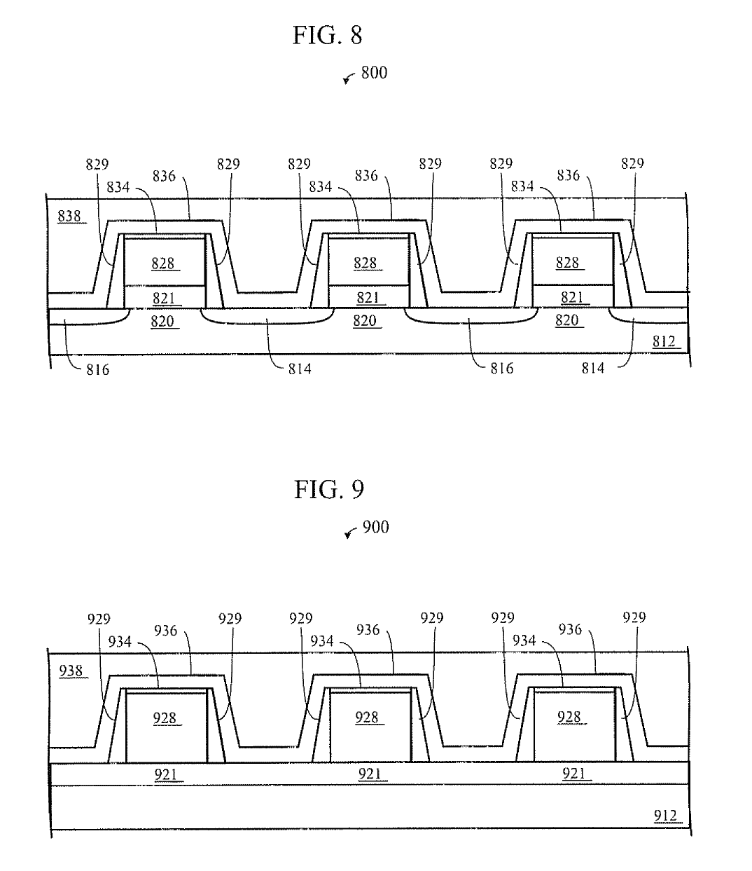

FIG. 8 shows three exemplary non-volatile memory (NVM) cells 800 (compare 500), according to an embodiment of the disclosure. Generally, this represents a SONOS NAND architecture. Some features of the cell may be exaggerated, or stylized, also for illustrative clarity. The principles discussed in this, and subsequent embodiments, are merely exemplary, and can readily be applied to other architectures.

Generally, in each of the three cells 800, a charge storage stack 821, which may be an ONO stack (which usually contains a trapping layer such as nitride), is disposed atop a channel 820 which is defined (located) between two (source or drain) diffusions 814 and 816 in a substrate 812. A gate electrode 828 is formed atop the ONO stack 821. Sidewall spacers 829 may be formed on opposite sides of the gate electrode 828.

Typically in SONOS, only the gate electrode is silicided. This is indicated by layer 834 of thin metal (cobalt or titanium or nickel, typically 20 nm-200 nm) covering the gate 828. Optionally, the gate electrode could be a silicide (such as tungsten silicide) or could be a metal (such as tungsten) sitting on top of polysilicon. Similarly, MONOS, TANOS and split-gate or other trapping layer structures may be produced as would be known to one of skill in the art.

Next, a thin film cover liner 836 is deposited on the surface of the substrate 812, covering the entire NVM cell 800 (and neighboring cells on the wafer), including covering the gate electrode 828 and the two diffusions 814 and 816.

The cover liner 836 is deposited as a continuous layer, and may have a thickness in the range of 10 nm-200 nm.

Whereas a cover liner is typically (in the prior art) silicon nitride (SiN), according to an embodiment of the disclosure the cover liner 836 is formed as a continuous layer of silicon oxy-nitride (SiON), and may have a thickness in the range of 10 nm-200 nm, such as 20 nm-70 nm.

SiON, as the chemical formulation implies, has oxygen incorporated into the silicon nitride film during the deposition process. Optionally, the oxygen is included by reacting N2O, NH3 and SiH4 in an N2 ambient. SiON exhibits less stress than Nitride and its contact etch stop properties can be tailored to correspond to that of silicon nitride. Besides its use as a passivation layer (it can be modified to allow or block UV transmission) it may also be used as gate oxide material (where it helps prevent boron out diffusion).

It may be noted that, when a thin film of SiON is applied as a liner structure, RAC characteristics may dramatically be improved, due to reduced stress and optionally protection from plasma induced charges.

Next, an inter-layer dielectric (ILD) layer 838 is disposed over the cover liner 836. The ILD layer 838 may optionally be oxide (SiO2), deposited by a conventional oxide deposition process to a thickness in the range of 700 nm-1200 nm.

### A Fifth Embodiment

FIG. 9 shows three exemplary non-volatile memory (NVM) cells 900 (compare 500), according to an embodiment of the disclosure. Generally, this represents a DPP NROM architecture, with CESL. Some features of the cell may be exaggerated, or stylized, also for illustrative clarity. The principles discussed in this, and subsequent embodiments, are merely exemplary, and can readily be applied to other architectures.

Generally, in each of the three cells 900, a charge storage stack 921, which may be an ONO stack (which usually contains a trapping layer, such as nitride), is disposed on a substrate 912. A gate electrode 928 is formed atop the charge storage stack 921. Sidewall spacers 929 may be formed on opposite sides of the gate electrode 928. Further process steps, and structures resulting from the process steps will now be described, which generally involve structures 930 overlying the basic memory cell to provide for interconnect.

A layer of thin metal (cobalt or titanium or nickel) 934 may be deposited atop the gate and diffusions, such as having a thickness in the range of 20 nm-200 nm. The metal is then silicided using a conventional salicidation process. (No patterning is necessary. Silicidation is self-aligned to the exposed silicon/poly-silicon.) This layer 934 is generally for the purpose of reducing the sheet resistance of the diffusion and poly-silicon areas.

Next, a thin film cover liner 936 is deposited on the surface of the substrate 912, covering the entire NVM cell 900 (and neighboring cells on the wafer), including covering the gate electrode 928 and the two diffusions 914 and 916.

The cover liner 936 is deposited as a continuous layer, and may have a thickness in the range of 10 nm-200 nm.

Whereas a cover liner is typically (in the prior art) silicon nitride (SiN), according to an embodiment of the disclosure the cover liner 936 is formed as a continuous layer of silicon oxy-nitride (SiON), and may have a thickness in the range of 10 nm-200 nm, such as 20 nm-70 nm.

SiON, as the chemical formulation implies, has oxygen incorporated into the silicon nitride film during the deposition process. Optionally, the oxygen is included by reacting N2O, NH3 and SiH4 in an N2 ambient. SiON exhibits less stress than Nitride and its contact etch stop properties can be tailored to correspond to that of silicon nitride. Besides its use as a passivation layer (it can be modified to allow or block UV transmission) it may also be used as gate oxide material (where it helps prevent boron out diffusion).

It may be noted that, when a thin film of SiON is applied as a liner structure, RAC characteristics may dramatically be improved, due to reduced stress and optionally protection from plasma induced charges.

Next, an inter-layer dielectric (ILD) layer 938 is disposed over the cover liner 936. The ILD layer 938 may optionally be oxide (SiO2), deposited by a conventional oxide deposition process to a thickness in the range of 700 nm-1200 nm.

While a number of exemplary aspects and embodiments have been discussed above, those of skill in the art will recognize certain modifications, permutations, additions and sub-combinations thereof. It is therefore intended that the following appended claims and claims hereafter introduced be interpreted to include all such modifications, permutations, additions and sub-combinations.

What is claimed is:

1. A non-volatile memory (NVM) cell comprising:
a channel defined between two diffusions in a semiconductor substrate;
a charge storage stack or element disposed atop the channel;
a gate electrode disposed atop the charge storage stack or element;
a buffer layer; and
a contact etch stop layer (CESL) deposited as a thin film, covering at least the two diffusions;
wherein:
the CESL comprises silicon oxy-nitride (SiON).

2. The NVM cell of claim 1, wherein:
the NVM cell is inclusive of, but not limited to, NROM, SONOS, SANOS, MANOS, TANOS and Floating Gate (FG) cells.

3. The NVM cell of claim 1, wherein:
the CESL has a thickness in the range of 10 nm-200 nm.

4. The NVM cell of claim 3, wherein:
the CESL has a thickness in the range of 20 nm-70 nm.

5. The NVM cell of claim 1, wherein:
the CESL also covers the gate electrode.

6. The NVM cell of claim 1, further comprising:
sidewall spacers formed on opposite sides of the gate electrode.

7. The NVM cell of claim 1, further comprising:
an inter-layer dielectric (ILD) layer disposed over the CESL.

8. The NVM cell of claim 7, wherein:
the ILD layer comprises oxide, and has thickness in the range of 700 nm-1200 nm.

9. The NVM cell of claim 8, further comprising:
contact openings formed through the ILD to the two diffusions; and
a conductive material filing the contact openings;
wherein the conductive material is selected from the group consisting of metal and polysilicon.

10. The NVM cell of claim 9 further comprising:
an oxy nitride (SiON) layer in lieu of a nitride layer (SiN) disposed atop the ILD layer prior to optional copper metalization.

11. The NVM cell of claim 9, further comprising:
a patterned metal layer disposed atop the ILD.

12. The NVM cell of claim 11, further comprising:
a layer of passivating material disposed atop the patterned metal layer.

13. The NVM cell of claim 1, wherein:
the CESL extends as a continuous layer over the two diffusions and the gate electrode.

14. The NVM cell of claim 1, wherein:
the CESL extends as a discontinuous layer over the two diffusions and the gate electrode and comprises a material selected from the group consisting of silicon oxy-nitride (SiON) and silicon nitride (SiN).

15. The NVM cell of claim 1, wherein:
the CESL comprises separate segments over the two diffusions.
